(19) United States
(12) Patent Application Publication
(10) Pub. No.: US 2005/0185380 A1
(43) Pub. Date: Aug. 25, 2005

(54) Dissipation structure and method for backlight inverter

(76) Inventor: Wen-Shu Lee, San Chung City (TW)

Correspondence Address: RABIN & BERDO, P.C., Suite 500, 1101 14th Street, N.W., Washington, DC, 20005, US

(21) Appl. No.: 11/025,044

(22) Filed: Dec. 30, 2004

(30) Foreign Application Priority Data
Feb. 24, 2004 (TW) 93104659

(51) Int. Cl. H05K 7/20

(52) U.S. Cl. 361/704

(57) ABSTRACT

A dissipation structure of a backlight inverter is designed inside an outer housing for a notebook PC. In this dissipation structure, an inverter coil set is in contact with a dissipation plate to dissipate the heat generated by the inverter coil. In order to enhance the efficiency of dissipation, a sheet of thermally conductive material is added between the inverter coil set and the dissipation plate. The dissipation plate is a good thermal conductor, which can be replaced by an EMI shield or a metal alloy outer housing.

### RELATED APPLICATIONS

The present application is based on, and claims priority from, Taiwan Application Serial Number 93104659, filed Feb. 24, 2004, the disclosure of which is hereby incorporated by reference herein in its entirety.

### BACKGROUND

1. Field of Invention

The present invention relates to a dissipation structure of a backlight inverter. More particularly, the present invention relates to a dissipation structure of a backlight inverter installed in a notebook PC.

2. Description of Related Art

A notebook PC is one of the most popular information appliances. It is equipped with powerful computing performance as well as a light and thin body. Thus, the notebook PC has gradually replaced desktop PCs in many applications.

Due to continuing reductions in volume and weight, combined with enhanced computing performance, a heat dissipation issue of electronic components inside a notebook PC is now a big challenge.

FIG. 1 illustrates a conventional dissipation structure of a backlight inverter installed in a notebook PC. A backlight inverter module includes a printed circuit board 16 and an inverter coil set 14. The inverter module is attached to a lower outer housing 18 positioned near a hinge 30.

Because the inverter coil set 14 generates heat during voltage transformation, a regional high temperature (near the inverter coil set 14) occurs on an upper outer housing 10. The regional high temperature may hurt a user's hand or damage the upper outer housing 10.

### SUMMARY

It is therefore an objective of the present invention to provide a dissipation structure of a backlight inverter so as to dissipate the heat generated by the inverter coil evenly and effectively.

In accordance with the foregoing and other objectives of the present invention, a dissipation structure of a backlight inverter is designed inside an outer housing for a notebook PC. In this dissipation structure, an inverter coil set is in contact with a dissipation plate to dissipate the heat generated by the inverter coil. In order to enhance the efficiency of dissipation, a sheet of thermally conductive material is added between the inverter coil set and the dissipation plate. The dissipation plate is a good thermal conductor, which can be replaced by an EMI shield, an aluminum-magnesium alloy outer housing or a titanium alloy outer housing.

Thus, applying the dissipation structure of a backlight inverter in a notebook PC can effectively and evenly dissipate the heat generated by the inverter out of the notebook PC. Replacing the dissipation plate with the thermally conductive outer housing, such as aluminum-magnesium alloy or titanium alloy, will reduce material usage and manufacturing costs.

It is to be understood that both the foregoing general description and the following detailed description are examples, and are intended to provide a further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a conventional dissipation structure of a backlight inverter installed in a notebook PC; and

FIG. 2 illustrates a dissipation structure of a backlight inverter installed in a notebook PC according to one preferred embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In order to resolve the regional high temperature caused by the backlight inverter, the present invention discloses a dissipation plate in contact with the backlight inverter. A preferred embodiment is provided below to describe the present invention in detail.

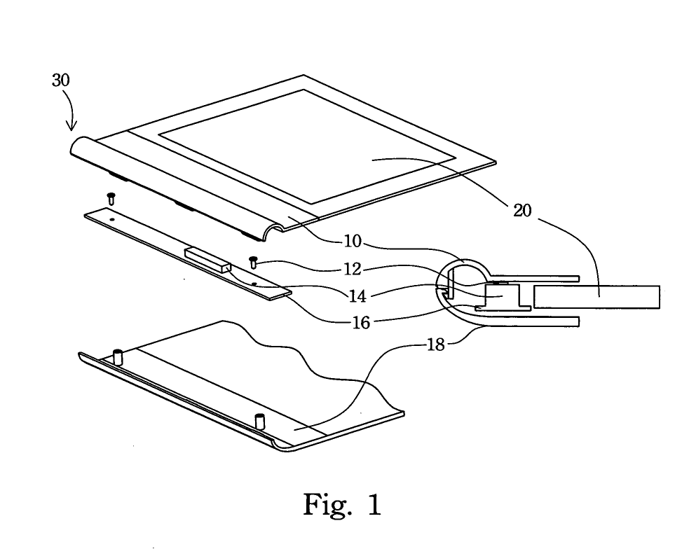

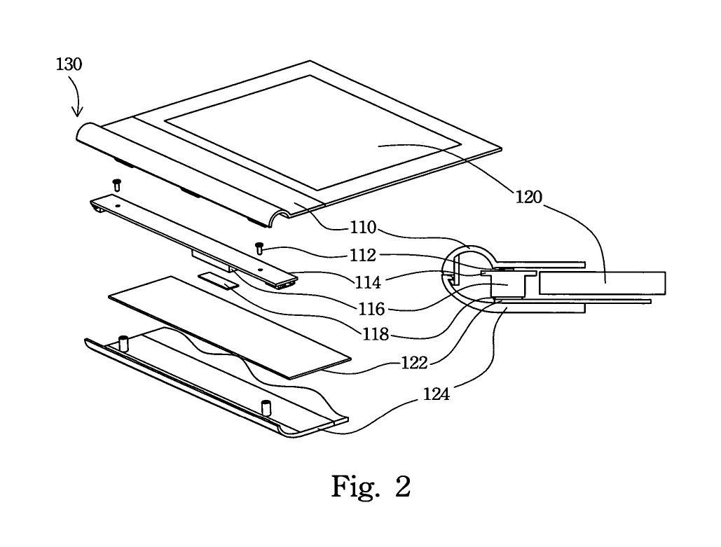

FIG. 2 illustrates a dissipation structure of a backlight inverter installed in a notebook PC according to one preferred embodiment of this invention. In one preferred embodiment of present invention, the backlight inverter module includes a printed circuit board 114 and an inverter coil set 116. An extra dissipation plate 122 is added in contact with a lower outer housing 124, as compared with conventional inverter structure (FIG. 1). Moreover, the backlight inverter module is turned around so that the inverter coil set 116 can be in contact with the dissipation plate 122. The backlight inverter module is secured to the lower outer housing 124 by means of screws 112.

To conduct heat evenly and effectively between the inverter coil set 116 and the dissipation plate 122, a sheet of thermally conductive material 118 is added between the inverter coil set 116 and the dissipation plate 122. The thermally conductive material 118 can be silicon, epoxy or other thermally conductive materials.

In this preferred embodiment, the dissipation plate 122 can extend to a position under a liquid crystal panel 120. The dissipation plate 122 is a thermally conductive plate, which can be made of metal or the like. An electromagnetic radiation interference shield can be a dissipation plate. In addition, the lower outer housing 124 can serve as the dissipation plate if the lower outer housing 124 itself is a thermally conductive material, such as aluminum-magnesium alloy or titanium alloy.

According to the preferred embodiment described above, applying the dissipation structure of a backlight inverter in a notebook PC can effectively and evenly dissipate the heat generated by the inverter out of the notebook PC. Replacing the dissipation plate with the thermally conductive outer housing, such as aluminum-magnesium alloy or titanium alloy, will reduce material usage and manufacturing costs.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A dissipation structure of a backlight inverter installed in a notebook PC, said dissipation structure comprising:
an outer housing;
a dissipation plate, positioned in contact with said outer housing;
an inverter module, having an inverter coil set, contacting said dissipation plate; and
a thermally conductive material, positioned between said inverter coil set and said dissipation plate.

2. The dissipation structure of claim 1, wherein said inverter module is secured to said outer housing by means of screws.

3. The dissipation structure of claim 1, wherein said dissipation plate is an electromagnetic radiation interference shield.

4. The dissipation structure of claim 1, wherein said dissipation plate is an aluminum-magnesium alloy outer housing.

5. The dissipation structure of claim 1, wherein said dissipation plate is a titanium alloy outer housing.

6. A dissipation method for of a backlight inverter, utilized in a notebook PC, said dissipation method comprising:
securing a dissipation plate to an outer housing;
securing an inverter module to said outer housing, wherein said inverter module is in contact with said dissipation plate; and
positioning thermally conductive material between said inverter module and said dissipation plate.

7. The dissipation method of claim 1, wherein said inverter module is secured to said outer housing by screwing.

8. The dissipation method of claim 1, wherein said dissipation plate is an electromagnetic radiation interference shield.

9. The dissipation method of claim 1, wherein said dissipation plate is an aluminum-magnesium alloy outer housing.

10. The dissipation method of claim 1, wherein said dissipation plate is a titanium alloy outer housing.
